(19) United States
(12) Patent Application Publication
(10) Pub. No.: US 2017/0301578 A1
(43) Pub. Date: Oct. 19, 2017

(54) FOCUS RING ASSEMBLY AND A METHOD OF PROCESSING A SUBSTRATE USING THE SAME

(71) Applicant: SAMSUNG ELECTRONICS CO., LTD., Suwon-si (KR)

(72) Inventors: Jung-Pyo HONG, Seoul (KR); Sang-Dong Kwon, Seoul (KR); Kwang-Nam Kim, Suwon-si (KR); Jong-Woo Sun, Hwaseong-si (KR); Sang-Rok Oh, Yongin-si (KR)

(21) Appl. No.: 15/396,929

(22) Filed: Jan. 3, 2017

(30) Foreign Application Priority Data
Apr. 15, 2016 (KR) 10-2016-0046283

(51) Int. Cl. H01L 21/687; H01J 37/32; B08B 9/08; B08B 7/00; H01L 21/67

(52) U.S. Cl. CPC H01L 21/68721; H01L 21/67069; H01J 37/32733; B08B 9/08; H01J 37/3244; H01J 37/32862; H01J 37/32853; B08B 7/00; H01J 37/32642; H01J 37/32633; H01J 2237/002; H01J 2237/334

(57) ABSTRACT

A method of processing a substrate including loading the substrate into a plasma-processing apparatus. The plasma-processing apparatus includes a focus ring. The substrate is processed in the plasma-processing apparatus using plasma. The substrate is unloaded from the plasma-processing apparatus. A layer is formed on the focus ring. The layer is formed by an in-situ process in the plasma-processing apparatus.

### CROSS-REFERENCE TO RELATED APPLICATION

This application claims priority under 35 U.S.C. §119 to Korean Patent Application No. 10-2016-0046283, filed on Apr. 15, 2016 in the Korean Intellectual Property Office, the disclosure of which is incorporated by reference herein in its entirety.

### TECHNICAL FIELD

The present inventive concept relates to a focus ring assembly and a method of processing a substrate using the same.

### DISCUSSION OF RELATED ART

A plasma-processing apparatus may be configured to etch a layer on a semiconductor substrate using plasma. Alternatively, a plasma-processing apparatus may be configured to form a layer on a semiconductor substrate using plasma. The plasma-processing apparatus may include a plasma chamber, an electrostatic chuck (ESC), an antenna and a focus ring. The ESC may be disposed on a bottom surface of the plasma chamber. The semiconductor substrate may be disposed on an upper surface of the ESC. The antenna may be arranged at an upper region of the plasma chamber. The focus ring may be configured to surround the semiconductor substrate.

The focus ring may become worn by the plasma. The worn focus ring may cause non-uniform plasma distribution in the upper region of the plasma chamber. The non-uniform plasma distribution may result in an uneven thickness of an etched layer on the semiconductor substrate.

Accordingly, the worn focus ring is periodically replaced with a new focus ring. To replace a worn focus ring, the plasma-processing apparatus must be stopped. However, this may cause an operation rate of the plasma-processing apparatus to be decreased.

### SUMMARY

Exemplary embodiments of the inventive concept provide a method of processing a substrate. In the method, the substrate is loaded into a plasma-processing apparatus. The plasma-processing apparatus includes a focus ring. The substrate is processed in the plasma-processing apparatus by using plasma. The substrate is unloaded from the plasma-processing apparatus. A layer is formed on the focus ring. The layer is formed by an in-situ process in the plasma-processing apparatus.

Exemplary embodiments of the inventive concept provide a focus ring assembly. The focus ring assembly includes a focus ring and a layer. The focus ring is configured be disposed on opposite sides of a substrate when the substrate is etched by plasma. The layer is formed on the focus ring. The layer includes a material different from a material of the focus ring.

Exemplary embodiments of the inventive concept provide a method of manufacturing a semiconductor. A plasma-processing apparatus including a focus ring is provided. A layer is formed on the focus ring. The layer is formed by an in-situ process in the plasma-processing apparatus. The layer is formed on the focus ring after a thickness of the focus ring has been reduced by a predetermined amount. The thickness of the layer corresponds to the thickness of the focus ring that has been reduced.

### BRIEF DESCRIPTION OF THE DRAWINGS

The above and/or other features of the inventive concept will be more apparent by describing in detail exemplary embodiments thereof with reference to the accompanying drawings, in which:

FIG. 1 is a cross-sectional view illustrating a plasma-processing apparatus according to an exemplary embodiment of the inventive concept;

FIG. 2 is an enlarged cross-sectional view illustrating a focus ring assembly of a plasma-processing apparatus of FIG. 1 according to an exemplary embodiment of the inventive concept;

FIGS. 3 to 5 are cross-sectional views illustrating a method of processing a substrate according to an exemplary embodiment of the inventive concept;

FIGS. 6 to 12 are cross-sectional views illustrating a method of forming a thickness-compensating layer on a worn surface of a focus ring according to an exemplary embodiment of the inventive concept; and

FIG. 13 is a cross-sectional view illustrating a focus ring assembly according to an exemplary embodiment of the inventive concept.

### DETAILED DESCRIPTION OF THE EMBODIMENTS

Hereinafter, exemplary embodiments of the inventive concept will be explained in detail with reference to the accompanying drawings.

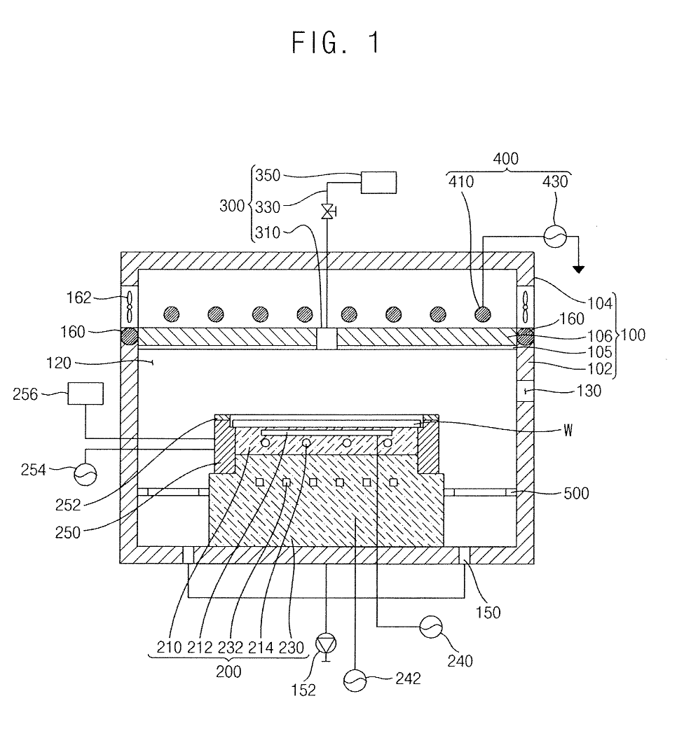

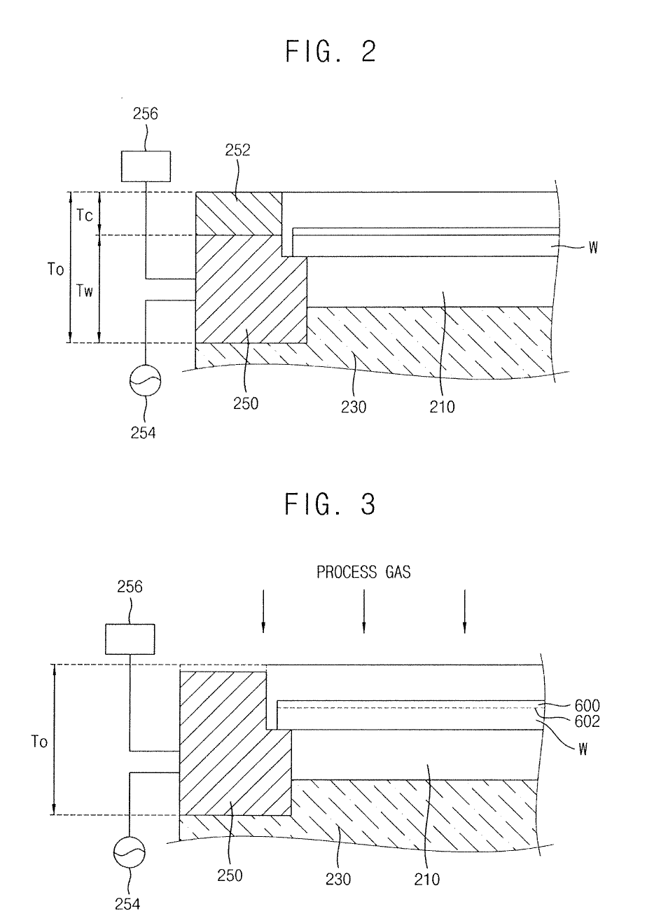

FIG. 1 is a cross-sectional view illustrating a plasma-processing apparatus according to an exemplary embodiment of the inventive concept. FIG. 2 is an enlarged cross-sectional view illustrating a focus ring assembly of a plasma-processing apparatus of FIG. 1 according to an exemplary embodiment of the inventive concept.

Referring to FIG. 1, a plasma-processing apparatus may include a plasma chamber 100, a heating unit 160, a cooling unit 162, a substrate-supporting unit 200, a gas-supplying unit 300, a plasma-generating unit 400 and a baffle 500.

The plasma chamber 100 may be configured to receive a substrate W. The substrate W may include a semiconductor substrate or a glass substrate; however, exemplary embodiments of the inventive concept are not limited thereto. The plasma chamber 100 may have a cylindrical shape. Alternatively, the plasma chamber 100 may have various shapes, such as a rectangular parallelepiped shape.

The plasma chamber 100 may include a housing 102, a cover 104, a protecting layer 105 and a dielectric plate 106. The housing 102 may have a cylindrical shape. The cylindrical shape may have an opened upper surface. An entrance 130 may be formed at a sidewall of the housing 102. The substrate W may be loaded and/or unloaded into and/or from the housing 102 through the entrance 130. The housing 102 may include a metal; however, exemplary embodiments of the inventive concept are not limited thereto. The housing 102 may include various materials.

The dielectric plate 106 may be arranged on an upper surface of the housing 102. The cover 104 may have a cylindrical shape. The cylindrical shape may have an opened lower surface. The cover 104 may be configured to cover the housing 102. The cover 104 may include a metal; however, exemplary embodiments of the inventive concept are not limited thereto. The cover 104 may include various materials.

The housing 102 and the cover 104 may define an inner space. The dielectric plate 106 may be configured to partition the inner space defined by the housing 102 and the cover 104. The dielectric plate 106 may define a substrate-processing region 120 in the inner space. The substrate W may be processed using plasma in the substrate-processing region 120. The dielectric plate 106 may have a circular shape; however, exemplary embodiments of the inventive concept are not limited thereto. The dielectric plate 106 may have various shapes. The dielectric plate 106 may have a diameter corresponding to an inner diameter of the housing 102.

The dielectric plate 106 may be arranged between the housing 102 and the cover 104. Alternatively, the dielectric plate 106 may be arranged inside the housing 102. The dielectric plate 106 may also be arranged inside the cover 104. When the dielectric plate 106 is arranged between the housing 102 and the cover 104, the substrate-processing region 120 may be defined by the housing 102 and the dielectric plate 106. The dielectric plate 106 may include a dielectric material. For example, the dielectric plate 106 may include silicon oxide or silicon aluminum oxide; however, exemplary embodiments of the inventive concept are not limited thereto.

The protecting layer 105 may be arranged on a lower surface of the dielectric plate 106. The protecting layer 105 may be configured to function as to prevent damage of the dielectric plate 106 in a substrate-processing process. The protecting layer 105 may also be configured to prevent particles from being generated from the dielectric plate 106. The protecting layer 105 may include yttrium oxide; however, exemplary embodiments of the inventive concept are not limited thereto.

An exhaust 150 may be arranged on the bottom surface of the plasma chamber 100. The exhaust 150 may be connected to an exhaust pump 152. The exhaust 150 may be connected to the exhaust pump 152 through an exhaust line. The exhaust pump 152 may be configured to provide the exhaust 150 with a vacuum through the exhaust line. Byproducts generated in the substrate-processing process and remaining plasma in the plasma chamber 100 may be removed from the plasma chamber 100 by the vacuum provided from the exhaust pump 152.

The substrate-supporting unit 200 may be arranged in the substrate-processing region 120. The substrate-supporting unit 200 may be configured to support the substrate W. The substrate-supporting unit 200 may include an electrostatic chuck (ESC). The ESC may be configured to support the substrate W using an electrostatic force. Alternatively, the substrate-supporting unit 200 may have a structure configured to mechanically support the substrate W.

When the substrate-supporting unit 200 includes the ESC, the substrate-supporting unit 200 may include a dielectric layer 210, a focus ring assembly and a base 230. The substrate W may be disposed on an upper surface of the dielectric layer 210. Thus, the upper surface of the dielectric layer 210 may be in direct contact with a lower surface of the substrate W. The dielectric layer 210 may have a circular shape. The dielectric layer 210 may have a radius smaller than a radius of the substrate W. The dielectric layer 210 may include a ceramic; however, exemplary embodiments of the inventive concept are not limited thereto.

A lower electrode 212 may be arranged in the dielectric layer 210. A main power source 240 may be connected to the lower electrode 212. The lower electrode 212 may receive the electrostatic force from the main power source 240. Accordingly, the substrate W may be fixed to the dielectric layer 210. The lower electrode 212 may include a monopole electrode.

A heater 214 may be arranged in the dielectric layer 210. The heater 214 may be configured to heat the substrate W. The heater 214 may be arranged below the lower electrode 212. The heater 214 may include a spiral coil.

The base 230 may be configured to support the dielectric layer 210. The base 230 may be arranged below the dielectric layer 210. The base 230 may be combined with the dielectric layer 210. An upper surface of the base 230 may include an edge portion. The upper surface of the base 230 may further include a central portion. The central portion of the base 230 may protrude from the edge portion of the base 230. The central portion of the base 230 may have an area corresponding to a bottom surface of the dielectric layer 210.

A cooling passageway 232 may be formed in the base 230. A cooling fluid may flow through the cooling passageway 232. The cooling passageway 232 may have a spiral shape; however, exemplary embodiments of the inventive concept are not limited thereto.

A high frequency power source 242 may be positioned outside the plasma chamber 100. The base 230 may be connected to the high frequency power source 242. The high frequency power source 242 may supply power to the base 230. The power supplied to the base 230 may guide the plasma in the plasma chamber 100 from the plasma chamber 100 to the base 230. The base 230 may include a metal; however, exemplary embodiments of the inventive concept are not limited thereto.

The focus ring assembly may be configured to concentrate the plasma on the substrate W. The focus ring assembly may include a focus ring 250, a thickness-compensating layer 252, a bias-applying member 254, and a thickness-measuring unit 256.

The focus ring 250 may be arranged at an edge portion of the upper surface of the dielectric layer 210. The focus ring 250 may be configured to surround the substrate W. The focus ring 250 may include silicon oxide or silicon carbon; however, exemplary embodiments of the present invention are not limited thereto. The focus ring 250 may include various materials.

The focus ring 250 may include a single ring. Alternatively, the focus ring 250 may include a plurality of rings. For example, the focus ring 250 may include an inner ring and an outer ring. The outer ring may be configured to surround the inner ring.

A surface of the focus ring 250, e.g., an upper surface, may be worn during a processing of a layer, e.g., etching, on the substrate W. Further, after unloading the substrate W from the plasma chamber 100, the upper surface of the focus ring 250 may be worn during cleaning of the plasma chamber 100 by a dry etching process. The worn focus ring 250 may have a thickness Tw. The thickness Tw of the worn focus ring 250 may be smaller than an original thickness To of the focus ring 250. Since the worn focus ring 250 may be thin, changes of plasma sheath may occur. Accordingly, the plasma might not be uniformly distributed over the substrate W. The plasma distribution over an edge portion of the substrate W may be deteriorated.

Therefore, the worn focus ring 250 may be periodically replaced with a new focus ring. To exchange the worn focus ring 250 for the new focus ring, the worn focus ring 250 may be unloaded from the plasma chamber 100. Thus, an operation of the plasma-processing apparatus may be stopped. Accordingly, an operation rate of the plasma-processing apparatus may be decreased.

The thickness-compensating layer 252 may be formed on the upper surface of the worn focus ring 250. The thickness-compensating layer 252 may have a thickness Tc. The thickness Tc of the thickness-compensating layer 252 may be substantially the same as the thickness Tw of the worn focus ring 250. Thus, a thickness including the thickness Tw of the worn focus ring 250 and the thickness Tc of the thickness-compensating layer 252 may be substantially the same as the original thickness To of the focus ring 250. Accordingly, the thickness-compensating layer 252 may provide the worn focus ring 250 with a thickness substantially the same as the original thickness To of the focus ring 250.

The thickness-compensating layer 252 may be formed on the upper surface of the worn focus ring 250. The thickness-compensating layer 252 may be disposed on the upper surface of the worn focus ring 250 by an in-situ process performed in the plasma chamber 100. After performing a dry etching process, a source gas may be introduced into the plasma chamber 100. Through an in-situ process, the source gas may form the thickness-compensating layer 252 on the upper surface of the worn focus ring 250. Therefore, the thickness-compensating layer 252 may be formed without unloading the worn focus ring 250 from the plasma chamber 100. Accordingly, the thickness-compensating layer 252 may be formed on the upper surface of the worn focus ring 250 without stopping the plasma-processing apparatus. Therefore, the operation rate of the plasma-processing apparatus may be increased.

The thickness-compensating layer 252 may include a material substantially the same as a material of the focus ring 250. For example, when the focus ring 250 includes silicon oxide, the thickness-compensating layer 252 may include silicon oxide. When the focus ring 250 and the thickness-compensating layer 252 each include silicon oxide, the source gas introduced into the plasma chamber 100 may include SiH₄/N₂O, TEOS/O₂/N₂, triethoxysilane (TriEOS), tetramethyl orthosilicate (TMOS), or TriMOS; however, exemplary embodiments of the present invention are not limited thereto. When the focus ring 250 includes silicon carbide, the source gas introduced into the plasma chamber 100 may include a gas containing silicon carbide.

The bias-applying member 254 may be configured to apply a bias to the focus ring 250. The plasma generated from the source gas may be induced to the focus ring 250. The bias may be applied to the plasma induced to the focus ring 250 to form the thickness-compensating layer 252 on the upper surface of the worn focus ring 250.

Alternatively, the bias-applying member 254 may include the high frequency power source 242. The high frequency power source 242 may be parallely connected to the base 230. The high frequency power source 242 may also be parallel connected to the focus ring 250. A switch may selectively control the power applied to the base 230 and the focus ring 250 from the high frequency power source 242.

The thickness-measuring unit 256 may be configured to measure a thickness of the focus ring 250. The thickness-measuring unit 256 may measure the thicknesses of the focus ring 250 after the plasma etching process and the dry etching process. Since the original thickness To of the focus ring 250 may be determined, a worn thickness of the focus ring 250 may be obtained from a present thickness of the focus ring 250 measured by the thickness-measuring unit 256. Deposition recipes for providing the thickness-compensating layer 252 with a thickness corresponding to a worn thickness of the focus ring 250 measured by the thickness-measuring unit 256 may be set. For example, deposition rates, and material amounts used to compensate for particular levels of worn focus rings may be predetermined and stored in a computer memory. The thickness-measuring unit 256 may use electromagnetism, radiation, or an ultrasonic wave; however, exemplary embodiments of the present invention are not limited thereto.

The gas-supplying unit 300 may be configured to supply process gases to the substrate W supported by the substrate-supporting unit 200. The gas-supplying unit 300 may include a gas tank 350, a gas line 330 and an inlet port 310. The gas tank 350 may be configured to store the process gases. The gas line 330 may connect the gas tank 350 and the inlet port 310. The process gases in the gas tank 310 may be supplied to the inlet port 310 through the gas line 330.

The plasma-generating unit 400 may be configured to excite the process gas in the plasma chamber 100. Exciting the process gas may generate the plasma. The plasma-generating unit 400 may include an inductively coupled plasma-generating unit. The plasma-generating unit 400 may include an antenna 410 and a power source 430.

The antenna 410 may be arranged in a space defined by the dielectric plate 106 and the cover 104. The antenna 410 may have a spiral shape. The antenna 410 may be connected to the power source 430. The antenna 410 may receive power from the power source 430. The antenna 410 may form a discharge space in the space defined by the dielectric plate 106 and the cover 104. The process gas in the discharge space may be excited to generate the plasma.

The baffle 500 may be configured to uniformly distribute the plasma in the substrate-processing region 120. The baffle 500 may be arranged between an inner surface of the plasma chamber 100 and the substrate-supporting unit 200 in the substrate-processing region 120. The baffle 500 may have an annular shape. Alternatively, the baffle 500 may have various shapes. The various shapes may correspond to shapes of a region where the baffle 500 may be arranged. A plurality of holes 502 may be vertically formed through the baffle 500.

The heating unit 160 may be arranged at both sides of the dielectric plate 106. The heating unit 160 may be configured to heat the edge portion of the dielectric plate 106. The heating unit 160 may be arranged in various other positions.

The cooling unit 162 may be configured to cool the dielectric plate 106. The cooling unit 162 may include a fan. The fan may be arranged on a sidewall of the cover 104. The fan may be configured to form an air current in the space defined by the dielectric plate 106 and the cover 104. Accordingly, the dielectric plate 106 might not overheat. The air current formed by the fan may transfer a temperature in the edge portion of the dielectric plate 106 to a central portion of the dielectric plate 106. The cooling unit 162 may further include an external power source. The external power source may be configured to supply power to the fan.

FIGS. 3 to 5 are cross-sectional views illustrating a method of processing a substrate according to an exemplary embodiment of the inventive concept.

Referring to FIG. 3, the focus ring 250 may have the original thickness To. The process gas may be introduced into the plasma chamber 100. The process gas may generate the plasma. The plasma generated from the process gas may etch a layer 600 on the substrate W. The layer 600 etched by the plasma generated from the process gas may form a pattern 602. Further, the upper surface of the focus ring 250 may be etched by the plasma. The substrate W may be a semiconductor substrate.

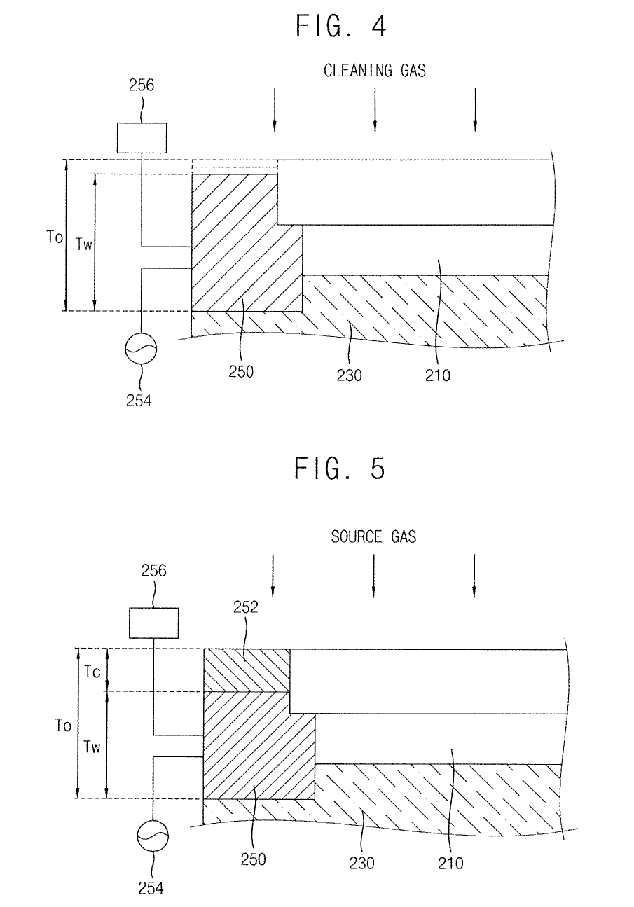

Referring to FIG. 4, the substrate W having the pattern 602 may be unloaded from the plasma chamber 100. To remove byproducts generated in the etching process, a cleaning gas may be introduced into the plasma chamber 100. The plasma generated from the cleaning gas may dry-etch the inner surface of the plasma chamber 100. Further, the upper surface of the focus ring 250 may also be etched by the plasma. Thus, the focus ring 250 may have a thickness Tw smaller than the original thickness To. The thickness Tw of the focus ring 250 may be smaller than the original thickness To of the focus ring 250 by a certain amount due to the two etching process.

Referring to FIG. 5, the thickness-measuring unit 256 may measure the thickness Tw of the focus ring 250. Since the original thickness To of the focus ring 250 may be previously determined, the worn thickness of the focus ring 250 may be obtained from the thickness Tw of the worn focus ring 250.

The bias-applying member 254 may apply the bias to the focus ring 250. The source gas may be introduced into the plasma chamber 100. The source gas may include SiH₄/N₂O, TEOS/O₂/N₂, triethoxysilane (TriEOS), tetramethyl orthosilicate (TMOS), or TriMOS; however, exemplary embodiments of the present invention are not limited thereto. The source gas may include 200SiH₄/100N₂O.

The plasma generated from the source gas may be induced to the focus ring 250. The plasma induced to the focus ring 250 may form the thickness-compensating layer 252 on the upper surface of the focus ring 250. The thickness-compensating layer 252 may have a thickness substantially the same as the worn thickness of the focus ring due to the two etching process. Thus, the thickness-compensating layer 252 may provide the focus ring 250 with a thickness that is substantially the same as the original thickness To of the focus ring 250.

The thickness-compensating layer 252 may be formed by the in-situ process in the plasma chamber 100. Thus, the focus ring 250 does not have to be unloaded from the plasma chamber 100. As a result, the thickness-compensating layer 252 may be formed on the upper surface of the worn focus ring 250 without stopping the plasma-processing apparatus. Therefore, the operation rate of the plasma-processing apparatus may be increased.

FIGS. 6 to 12 are cross-sectional views illustrating a method of forming a thickness-compensating layer on a worn surface of a focus ring according to an exemplary embodiment of the inventive concept.

Referring to FIG. 6, a TiN layer 610, an SiON layer 620, and an organic anti-reflective layer 630 may be sequentially formed on the upper surface of the substrate W. The focus ring 250 may have the original thickness To.

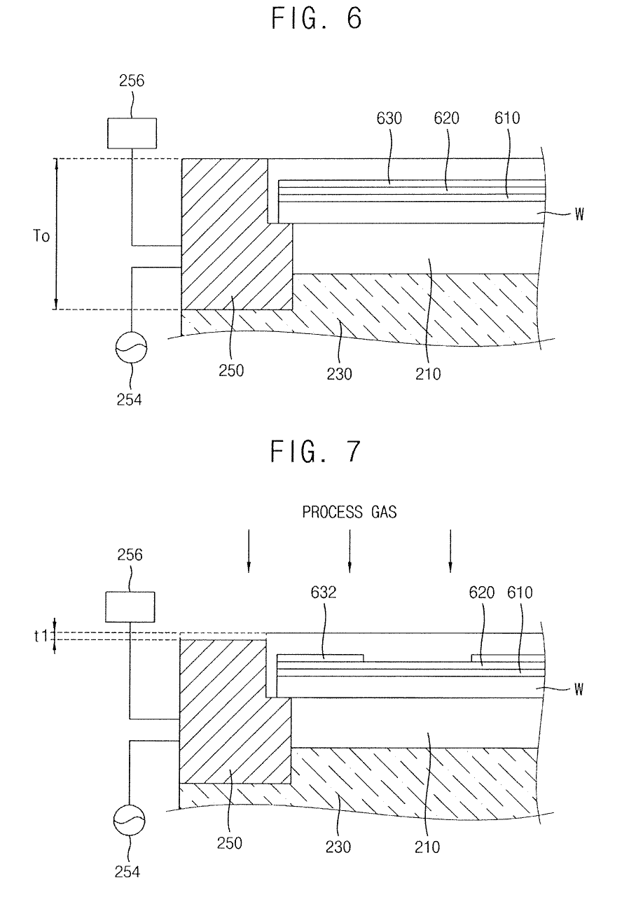

Referring to FIG. 7, a pressure, a power, and a magnetic flux may be applied to the plasma chamber 100. The pressure may be about 5 mT. The power may be about 400 W. The magnetic flux may be about 80 Wb. A process gas may be introduced into the plasma chamber. The process gas may include 20Cl₂/40CH₂F₂/130CF₄. Plasma generated from the process gas may etch the organic anti-reflective layer 630 of FIG. 6. The organic anti-reflective layer 630 etched by the plasma may form an organic anti-reflective pattern 632. The plasma may also etch the upper surface of the focus ring 250. The plasma may etch the upper surface of the focus ring 250 by a first thickness T1.

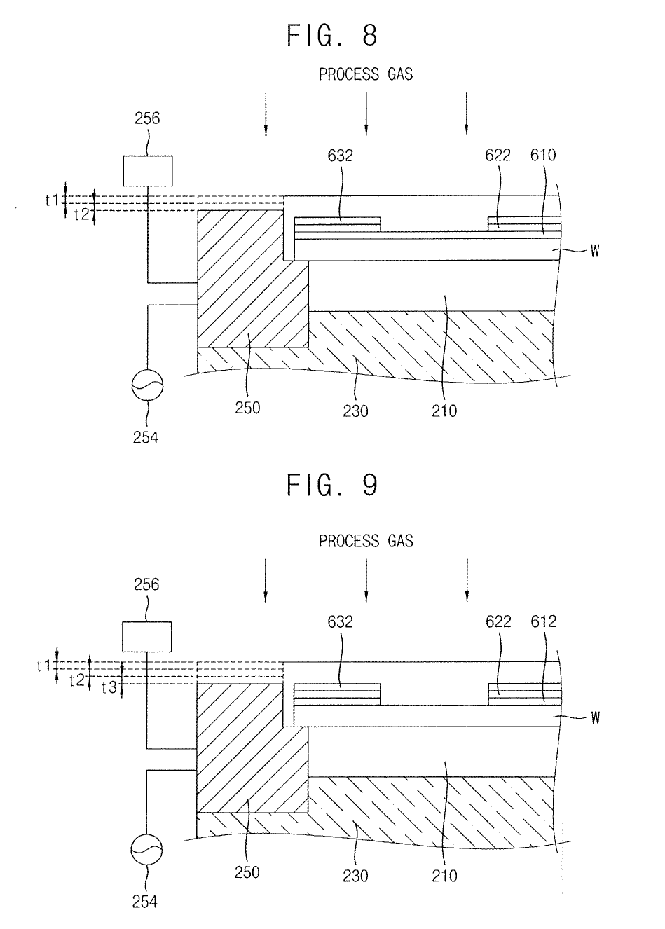

Referring to FIG. 8, a pressure, a power, and a magnetic flux may be further applied to the plasma chamber 100. The pressure may be about 5 mT. The power may be about 400 W. The magnetic flux may be about 70 Wb. A process gas may be introduced into the plasma chamber 100. The process gas may include 100CF₃/100CH₄/100O₂. Plasma generated from the process gas may etch the SiON layer 620 of FIG. 7. The SiON layer 620 etched by the process gas may form an SiON pattern 622. The plasma may also etch the upper surface of the focus ring 250. The plasma may etch the upper surface of the focus ring 250 by a second thickness T2.

Referring to FIG. 9, a pressure, a power, and a magnetic flux may be further applied to the plasma chamber 100. The pressure may be about 5 mT. The power may be about 700 W. The magnetic flux may be about 100 Wb. A process gas may be introduced into the plasma chamber 100. The process gas may include 60Cl₂/20CH₃/45N₂. Plasma generated from the process gas may etch the TiN layer 610 of FIG. 8. The TiN 610 layer etched by the process gas may form a TiN pattern 612. The plasma may also etch the upper surface of the focus ring 250. The plasma may etch the upper surface of the focus ring 250 by a third thickness T3.

The substrate W including the TiN pattern 612, the SiON pattern 622, and the organic anti-reflective pattern 632 may be unloaded from the plasma chamber 100.

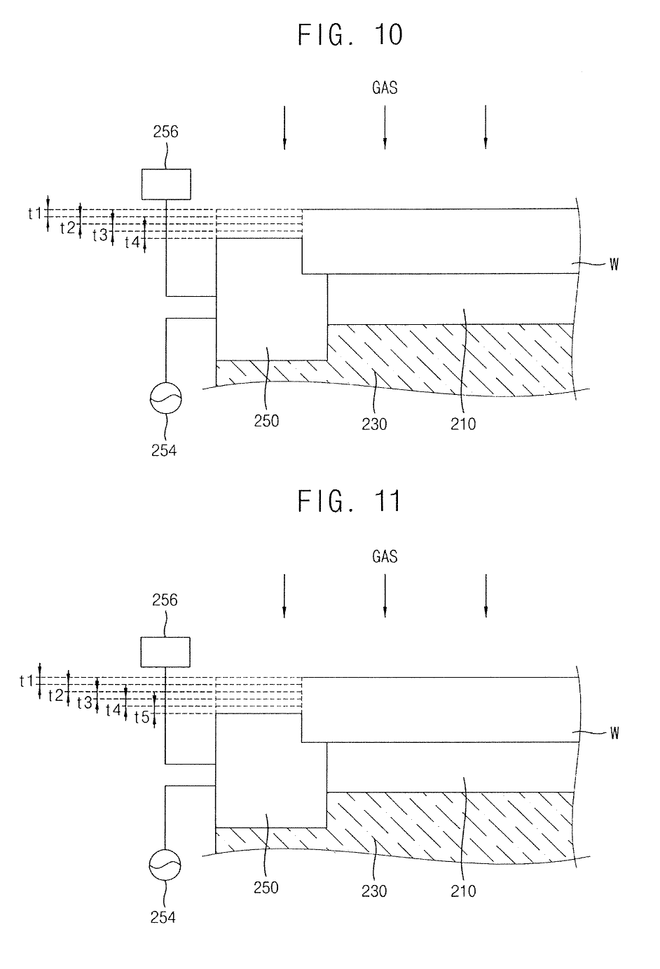

Referring to FIG. 10, a pressure and a power may be further applied to the plasma chamber 100. The pressure may be about 8 mT. The power may be about 1,500 W. A gas may be introduced into the plasma chamber 100. The gas may be a 200Cl₂ gas. The 200Cl₂ gas may generate plasma. The plasma generated from the 200Cl₂ gas may remove Ti in the byproducts. The plasma may also etch the upper surface of the focus ring 250. The plasma may etch the upper surface of the focus ring 250 by a fourth thickness T4.

Referring to FIG. 11, a pressure and a power may be further applied to the plasma chamber 100. The pressure may be about 20 mT. The power may be about 1,500 W. A gas may be introduced into the plasma chamber 100. The gas may be a 500NF₃ gas. The 500NF₃ gas may generate plasma. The plasma generated from the 500NF₃ gas may remove Si in the byproducts. The plasma may also etch the upper surface of the focus ring 250. The plasma may etch the upper surface of the focus ring 250 by a fifth thickness T5.

Accordingly, the focus ring 250 may have a thickness Tw subtracted from the original thickness To by a summed thickness of the first to fifth thicknesses T1, T2, T3, T4 and T5. Through the five etching processes, the thickness of the focus ring 250 may be reduced, for example, by the rate of about 27.6 nm/min.

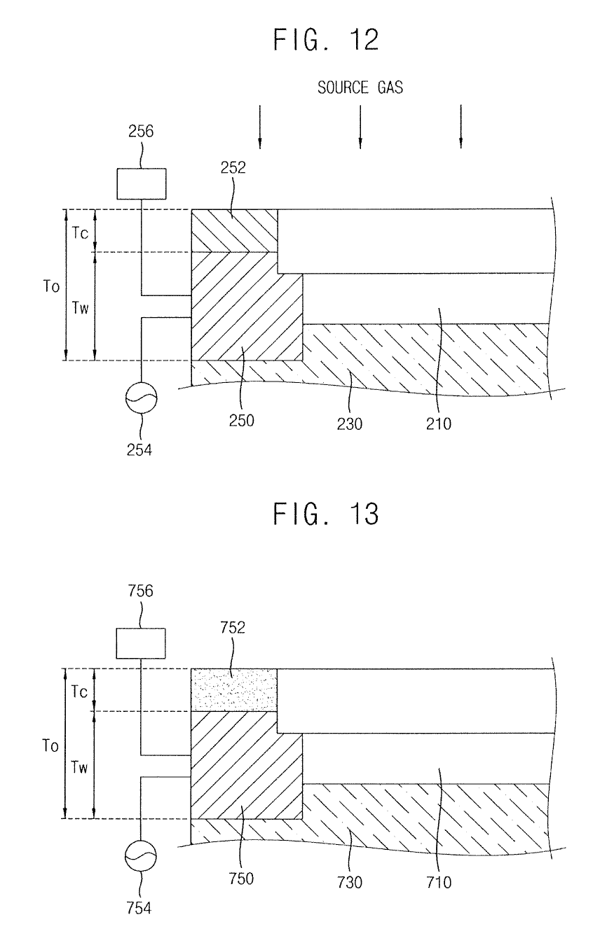

Referring to FIG. 12, the thickness-measuring unit 256 may be configured to measure the thickness of the worn focus ring 250. Since the original thickness To of the focus ring 250 was previously determined, a worn thickness Tw of the focus ring 250 may be obtained from the thickness of the focus ring 250 measured by the thickness-measuring unit 256.

The bias-applying member 254 may apply a bias to the focus ring 250. A pressure, a power and a magnetic flux may be further applied to the plasma chamber 100. The pressure may be about 10 mT. The power may be about 700 W. The magnetic flux may be about 150 Wb. A source gas may be introduced into the plasma chamber 100. The source gas may include 200SiH₄/100N₂O.

Plasma generated from the source gas may be induced to the focus ring 250. The plasma induced to the focus ring 250 may form the thickness-compensating layer 252. The thickness-compensating layer 252 may include silicon oxide on the upper surface of the focus ring 250. The thickness-compensating layer 252 may have a thickness substantially the same as a summed thickness of the first to fifth thicknesses T1, T2, T3, T4 and T5. Thus, the focus ring 250 may have a thickness substantially the same as the original thickness To by the thickness-compensating layer 252.

According to an exemplary embodiment of the inventive concept, the three plasma etching processes under the etching recipes and the two cleaning processes under the cleaning recipes may be performed. However, numbers and recipes of the plasma etching process and the cleaning process may be variously changed in accordance with numbers and materials of the layer on the substrate W.

FIG. 13 is a cross-sectional view illustrating a focus ring assembly according to an exemplary embodiment of the inventive concept.

Referring to FIG. 13, a focus ring assembly may include a focus ring 750, a thickness-compensating layer 752, a bias-applying member 754, and a thickness-measuring unit 756.

The focus ring 750, the bias-applying member 754, and the thickness-measuring unit 756 as illustrated in FIG. 13 may be substantially the same as the focus ring 250, the bias-applying member 254, and the thickness-measuring unit 256 as illustrated in FIG. 2, respectively. Accordingly, similar descriptions thereof may be omitted.

The thickness-compensating layer 752 may include a material different than a material of the focus ring 750. For example, an etching rate of the thickness-compensating layer 752 may be lower than an etching rate of the focus ring 750. Thus, the thickness-compensating layer 752 may be etched at a slower rate than the focus ring 750. Since the thickness-compensating layer 752 disposed on the focus ring 750 may be etched in advance than the focus ring 750, the focus ring 750 having the thickness-compensating layer 752 may be used for a longer time than the focus ring 250 having the thickness-compensating layer 252 as illustrated in FIG. 2.

When the focus ring 750 includes silicon oxide, the thickness-compensating layer 752 may include S₃N₃, SiC, B₄C, BN, Al₂O₃, AlN, Y₂O₃, or ZrO₂; however, exemplary embodiments of the present invention are not limited thereto. When the focus ring 750 includes silicon carbide, the thickness-compensating layer 752 may include a material having an etching selectivity lower than an etching selectivity of silicon carbide with respect to the plasma.

A process for forming the thickness-compensating layer 752 may be substantially the same as the process illustrated with reference to FIG. 9, except for the types of source gases. Accordingly, similar descriptions thereof may be omitted.

According to an exemplary embodiment of the present invention, the focus ring assembly may be used with the structure of the plasma-processing apparatus as illustrated in FIG. 1. Alternatively, the focus ring assembly may be used with other structures of plasma-processing apparatuses.

According to an exemplary embodiment of the present invention, the thickness-compensating layer may be formed on the worn surface of the focus ring in the in-situ process. The worn focus ring may be arranged in the plasma-processing apparatus in the in-situ process. Therefore, an operation of the plasma-processing apparatus does not have to be stopped to replace the worn focus ring with a new focus ring. Thus, an operation rate of the plasma-processing apparatus may be increased. Further, the thickness-compensating layer may have an etching selectivity slower than an etching selectivity of the focus ring. Therefore, an etched rate of the thickness-compensating layer by the plasma may be relatively slower.

As a result, the focus ring including the thickness-compensating layer may be used for a longer time and the operation rate of the plasma-processing apparatus may be increased.

The foregoing is illustrative of exemplary embodiments of the inventive concept and is not to be construed as limiting thereof. Although several exemplary embodiments of the inventive concept have been described herein, those skilled in the art will readily appreciate that various modifications in form and details may be made therein without materially departing from the present inventive concept. Accordingly, all such modifications are intended to be included within the scope of the present inventive concept as defined by the following claims.

What is claimed is:

1. A method of processing a substrate, the method comprising:
loading the substrate into a plasma-processing apparatus, the plasma-processing apparatus including a focus ring;
processing the substrate in the plasma-processing apparatus by using plasma;
unloading the substrate from the plasma-processing apparatus; and
forming a layer on the focus ring, wherein
the layer is formed by an in-situ process in the plasma-processing apparatus.

2. The method of claim 1, wherein forming the layer comprises:
applying a bias to the focus ring; and
providing a source gas into the plasma-processing apparatus.

3. The method of claim 2, wherein the focus ring comprises SiO₂, and the source gas comprises SiH₄/N₂O, TEOS/O₂/N₂, TriEOS, TMOS or TriMOS.

4. The method of claim 1, wherein the layer has a thickness substantially the same as a thickness of the focus ring worn by the plasma.

5. The method of claim 1, wherein the layer comprises a material substantially the same as a material of the focus ring.

6. The method of claim 1, wherein the layer comprises a material different from a material of the focus ring.

7. The method of claim 6, wherein the focus ring comprises SiO₂, and the source gas comprises S₃N₃, SiC, B₄C, BN, Al₂O₃, AlN, Y₂O₃ or ZrO₂.

8. The method of claim 1, further comprising measuring a thickness of the focus ring worn by the plasma.

9. The method of claim 1, further comprising performing an etching process for cleaning the plasma-processing apparatus.

10. The method of claim 9, wherein the layer has a thickness including a thickness of the focus ring worn by the etching process.

11. The method of claim 10, further comprising measuring the thickness of the focus ring worn by the etching process.

12. A focus ring assembly, comprising:
a focus ring configured to be disposed on opposite sides of a substrate when the substrate is etched by a plasma; and
a layer formed on the focus ring, wherein the layer includes a material different from a material of the focus ring.

13. The focus ring assembly of claim 12, wherein the thickness-compensating layer has an etching selectivity lower than an etching selectivity of the focus ring.

14. The focus ring assembly of claim 13, wherein the focus ring comprises SiO₂, and the source gas comprises S₃N₃, SiC, B₄C, BN, Al₂O₃, AlN, Y₂O₃ or ZrO₂.

15. The focus ring assembly of claim 12, further comprising:
a bias-applying member configured to apply a bias to the focus ring; and
a thickness-measuring unit configured to measure a thickness of the focus ring worn by the plasma.

16. The focus ring assembly of claim 12, wherein a thickness of the layer on the focus ring is substantially the same as a thickness of the focus ring removed by a prior plasma process.

17. A method of manufacturing a semiconductor, the method comprising:
providing a plasma-processing apparatus including a focus ring; and
forming a layer on the focus ring, wherein
the layer is formed by an in-situ process in the plasma-processing apparatus,
wherein the layer is formed on the focus ring after a thickness of the focus ring has been reduced by a predetermined amount,
wherein the thickness of the layer corresponds to the thickness of the focus ring that has been reduced.

18. The method of claim 17, wherein the thickness of the focus ring is reduced by processing a substrate in the plasma-processing apparatus with plasma.

19. The method of claim 17, wherein forming the layer comprises:
applying a bias to the focus ring; and
providing a source gas into the plasma-processing apparatus.

20. The method claim 17, wherein the layer comprises a material substantially the same as a material included in the focus ring.
